(19) United States
(12) Patent Application Publication
(10) Pub. No.: US 2009/0255578 A1
(43) Pub. Date: Oct. 15, 2009

(54) Plasma-treated photovoltaic devices

(75) Inventors: David Eaglesham, Perrysburg, OH (US); Anke Abken, Toledo, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/320,059

(22) Filed: Jan. 15, 2009

Related U.S. Application Data
(60) Provisional application No. 61/021,156, filed on Jan. 15, 2008.

(51) Int. Cl. H01L 31/0296; H01L 31/18; H01L 31/02

(52) U.S. Cl. 136/256; 438/93; 257/431; 136/252; 257/E21.09; 257/E31.015

(57) ABSTRACT

A method of manufacturing a thin film photovoltaic device includes depositing a first compound semiconductor layer on a substrate and exposing the device to plasma, the plasma treating the layer.

### CLAIM FOR PRIORITY

This application claims priority under 35 U.S.C. § 119(e) to Provisional U.S. Patent Application Ser. No. 61/021,156 filed on Jan. 15, 2008, which is hereby incorporated by reference.

### TECHNICAL FIELD

This invention relates to photovoltaic cells.

### BACKGROUND

During the fabrication of photovoltaic devices, layers of semiconductor material include an absorber layer, where the optical energy is converted into electrical energy. Some photovoltaic devices can use transparent thin films that are also conductors of electrical charge. The conductive thin films can be a transparent conductive oxide (TCO), such as fluorine-doped tin oxide, aluminum-doped zinc oxide, or indium tin oxide. The TCO can allow light to pass through to the active light absorbing material and also serves as an ohmic contact to transport photogenerated charge carriers away from the light absorbing material. A back electrode can be formed on the back surface of a semiconductor layer. The back electrode can include electrically conductive material, such as metallic silver, nickel, copper, aluminum, titanium, palladium, or any practical combination thereof, to provide electrical connection to the semiconductor layer. The back electrode can also be a semiconductor material or transparent conductive oxide. Doping the semiconductor layer can improve the efficiency of a photovoltaic device.

### SUMMARY

A method of manufacturing a thin film photovoltaic device can include depositing a first compound semiconductor layer on a substrate and exposing the device to plasma, the plasma treating the layer. The method of manufacturing a thin film photovoltaic device can further include applying a back contact such as a back metal contact to the compound semiconductor layer.

In some circumstances, the plasma treatment can be applied before applying a back metal contact. In other circumstances, the plasma treatment can be applied after applying a back contact.

The method of manufacturing a thin film photovoltaic device can further include applying a transparent conductive layer over the substrate. The method of manufacturing a thin film photovoltaic device can further include applying a second compound semiconductor layer over the first compound semiconductor layer. The method of manufacturing a thin film photovoltaic device can further include providing electrical connections connected to the photovoltaic device for collecting electrical energy produced by the photovoltaic device.

In some circumstances, the method of manufacturing a thin film photovoltaic device can include exposing the compound semiconductor layer to cadmium chloride processing before plasma treatment. The plasma treatment can be applied for approximately 5 minutes, approximately 10 minutes, approximately 15 minutes, approximately 20 minutes, approximately 25 minutes, or approximately 30 minutes for example. The plasma treatment can include reactive ion etching. The plasma treatment can be applied in a vacuum. The plasma treatment can be applied at atmospheric pressure.

A compound semiconductor based photovoltaic device can include a substrate and a plasma-treated compound semiconductor layer on a substrate. The plasma can include hydrogen plasma, nitrogen plasma, argon plasma, helium plasma, or oxygen plasma mixtures.

The compound semiconductor can be a cadmium telluride. The compound semiconductor can be a copper indium sulfide, copper indium gallium diselenide, or copper indium gallium diselenide sulfide. The compound semiconductor can be a cadmium sulfide. The substrate can be glass.

The compound semiconductor based photovoltaic device can further include a back metal contact over the semiconductor layer. The compound semiconductor based photovoltaic device can further include a transparent conductive layer over the substrate. The compound semiconductor based photovoltaic device can further include a second compound semiconductor layer over the first compound semiconductor layer.

A system for generating electrical energy can include a multilayered photovoltaic device, the photovoltaic device including a substrate, a plasma-treated first compound semiconductor layer on a substrate and electrical connections connected to the photovoltaic device for collecting electrical energy produced by the photovoltaic device.

### DESCRIPTION OF DRAWINGS

FIG. 1 is a schematic of a plasma-treated photovoltaic device.

FIG. 2 is a schematic of a plasma-treated photovoltaic device.

FIG. 3 is a schematic of a plasma-treated photovoltaic device.

FIG. 4 is a schematic of a plasma-treated photovoltaic system.

FIG. 5 is a schematic of a system for plasma-treating a substrate.

### DETAILED DESCRIPTION

A photovoltaic cell can include a transparent conductive layer on a surface of the substrate, a first semiconductor layer, the substrate supporting the semiconductor layer, and a metal layer in contact with the semiconductor layer. A photovoltaic cell can be processed with intentional plasma treatment.

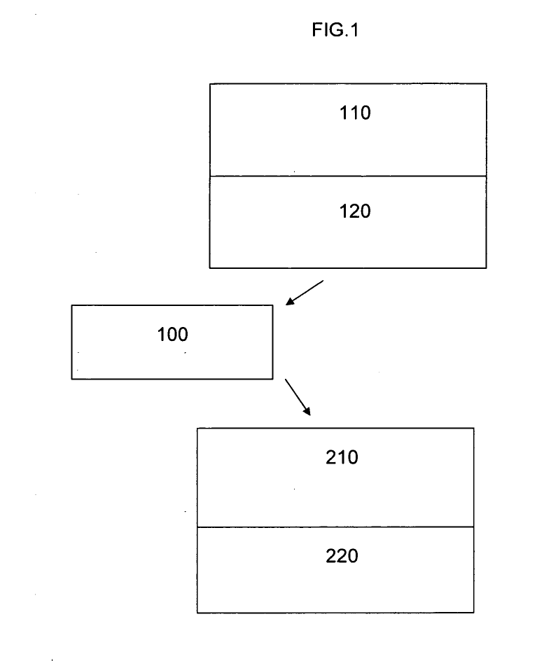

Referring to FIG. 1, a method of manufacturing a thin film photovoltaic device can include depositing a compound semiconductor layer 110 on a substrate 120 and exposing the device to plasma 100, the plasma treating the layer, thereby producing a photovoltaic device including a plasma-treated semiconductor layer 210 on a substrate 220. The method of manufacturing a thin film photovoltaic device can further include applying a back metal contact to the compound semiconductor layer. In some circumstances, the plasma treatment can be applied before applying a back metal contact. In other circumstances, the plasma treatment can be applied after applying a back metal contact. The plasma treatment can be applied for approximately 5 minutes, approximately 10 minutes, approximately 15 minutes, approximately 20 minutes, approximately 25 minutes, or approximately 30 minutes for example. Other time settings can also be applied.

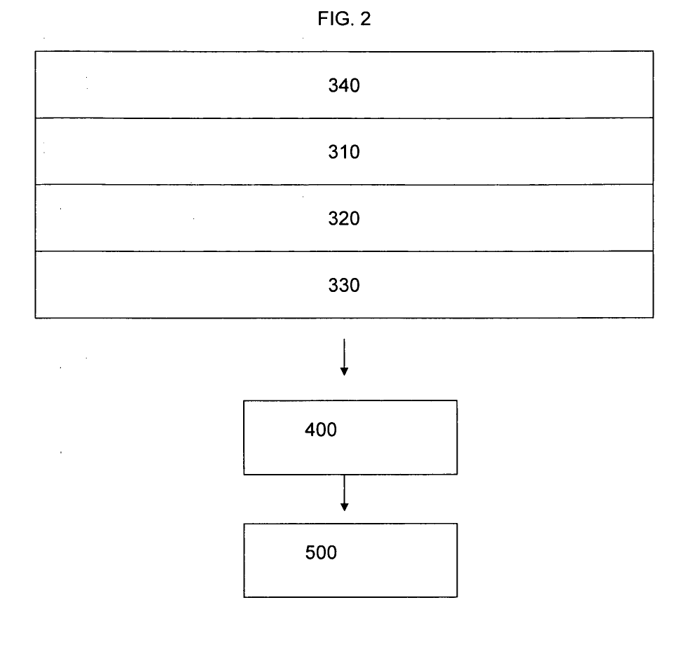

Referring to FIG. 2, a method of manufacturing a thin film photovoltaic device can further include applying a transparent conductive layer 320 over the substrate 330. A first compound semiconductor layer 310 can be deposited over the transparent conductive layer. The method of manufacturing a thin film photovoltaic device can further include applying a second compound semiconductor layer 340 over the first compound semiconductor layer. Either compound semiconductor layer can be exposed to cadmium chloride processing 400 before plasma treatment 500. The plasma treatment can be applied for approximately 5-20 minutes, thereby treating the semiconductor layer. The plasma treatment can include reactive ion etching. The plasma treatment can be applied in a vacuum. The plasma treatment can be applied at atmospheric pressure.

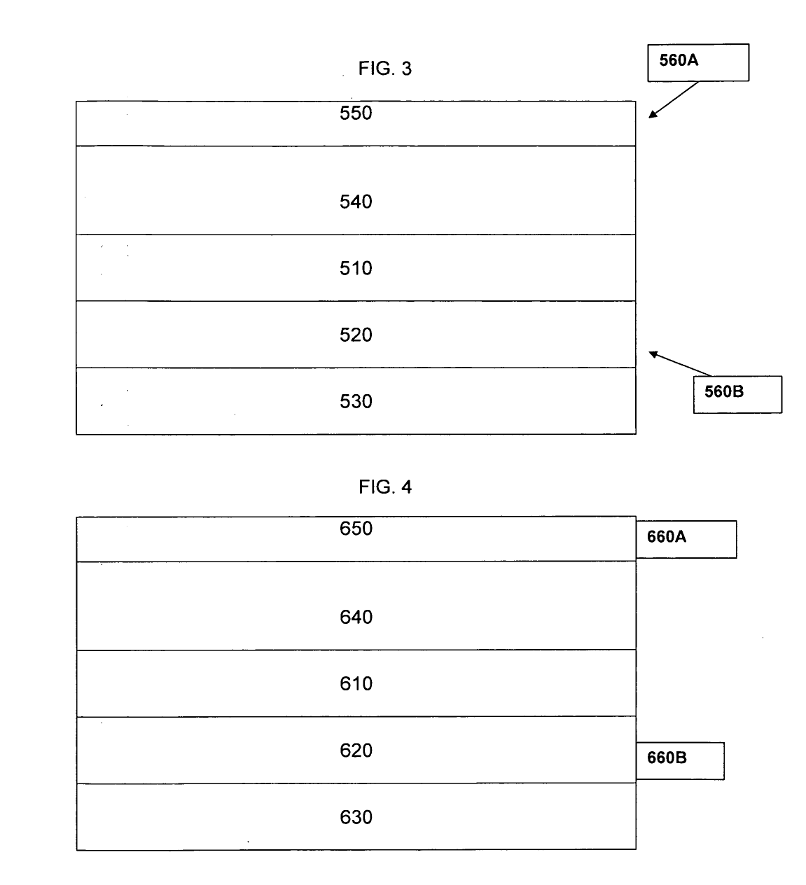

Referring to FIG. 3, a method of manufacturing a thin film photovoltaic device can further include applying a transparent conductive layer 520 over the substrate 530. A first compound semiconductor layer 510 can be deposited over the transparent conductive layer. The method of manufacturing a thin film photovoltaic device can further include applying a second compound semiconductor layer 540 over the first compound semiconductor layer. The first or second compound semiconductor layer can be a plasma-treated layer. The method can further include positioning a back contact 550, such as a back metal contact over a plasma-treated layer The method of manufacturing a thin film photovoltaic device can further include providing electrical connections 560A and 560B connected to the back metal contact and transparent conductive layer, respectively for collecting electrical energy produced by the photovoltaic device. The back contact can be a plasma treated layer.

Referring to FIG. 4, a system for generating electrical energy can include a multilayered photovoltaic device including a transparent conductive layer 620 over a substrate 630, a plasma-treated compound semiconductor layer 610 over a transparent conductive layer, a back metal contact 650 over a plasma-treated compound semiconductor layer, and electrical connections 660A and 660B connected to the back contact and transparent conductive layer, respectively. The back contact can be a plasma treated layer.

In some circumstances, a system can also include a second compound semiconductor layer 640 over a first compound semiconductor layer. A second compound semiconductor can be between a back metal contact and a first compound semiconductor layer.

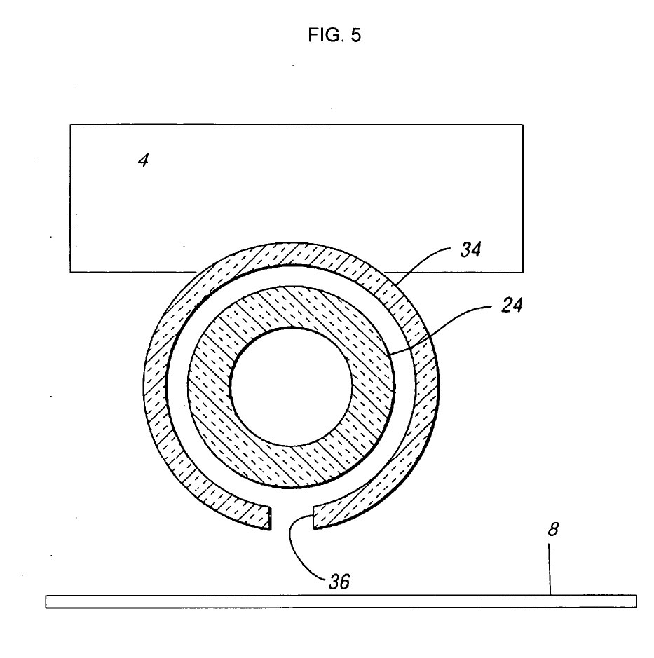

Referring to FIG. 5, a photovoltaic cell can be manufactured using a deposition system. A deposition system can include a distributor configured to provide a semiconductor coating on a substrate, a first power source configured to heat the distributor, and a plasma source positioned proximate to the distributor, the plasma source including an electrode configured to drive the plasma source, wherein the electrode is electrically independent from the first power source. A distributor can be an assembly, which includes a sheath tube 34. such as a ceramic sheath tube for example. In one aspect, a distributor can be an assembly including a sheath tube, a heater and a feed tube. A ceramic sheath tube can sheath a heater 24, such as permeable heater, which in turn, can sheath a feed tube. A sheath tube can include one or more distribution holes 36 configured to provide a semiconductor coating on a substrate 8. A plasma source can include an electrode configured to drive the plasma source. A system can also include an additional electrode configured to bias the plasma source with respect to the substrate. In certain circumstances, a distributor can include a pair of sheath tubes. In one embodiment, an electrode can be a spacer between a first sheath tube and a second sheath tube. A spacer can include a graphite cross-rod electrode. A spacer can include a non-metallic material, such as carbon, or other material that is resistant to corrosion. In one embodiment, a spacer can be a graphite spacer. An additional electrode can be a backcap 4 over a sheath tube. A backcap can be a graphite backcap. An insulator can be positioned between the spacer and the graphite back cap.

In some circumstances, the system or method can include an additional electrode configured to bias the plasma source with respect to the substrate. An electrode can be a backcap over a distributor. An electrode can include a non-metallic material, such as carbon, for example. In one example, an electrode can include graphite. An electrode can be a spacer. An electrode can be a backcap. A spacer can be a graphite spacer. A backcap can be a graphite backcap.

In other circumstances, a distributor can include a pair of sheath tubes including a first sheath tube and a second sheath tube. An electrode can be a spacer between a first sheath tube and a second sheath tube. An electrode can be a backcap over a first sheath tube and a second sheath tube.

Previous methods have included hydrogen plasma treatment in polycrystalline silicon based solar cell devices and thin film transistors that have a silicon nitride gate dielectric/amorphous silicon semiconductor interface. See for example U.S. Pat. No. 5,273,920, U.S. Pat. No. 5,281,546, M. J. Keeves, A. Turner, U. Schubert, P. A. Basore, M. A. Green, 20^{th} EU Photovoltaic Solar Energy Conf., Barcelona (2005) p 1305-1308; P. A. Basore, 4^{th} World Conf Photovoltaic Energy Conversion, Hawaii (2006) p 2089-2093, which are incorporated by reference herein. However, plasma treatments have not been applied in compound semiconductor (i.e. cadmium telluride or copper indium gallium diselenide sulfide) based photovoltaic cells.

A compound semiconductor based photovoltaic device can include a substrate and a plasma-treated compound semiconductor layer on a substrate. The plasma can include hydrogen plasma, nitrogen plasma, argon plasma, helium plasma, or oxygen plasma mixtures. The compound semiconductor can be a cadmium telluride. The compound semiconductor can be a copper indium sulfide, copper indium gallium diselenide, or copper indium gallium diselenide sulfide. The compound semiconductor can be a cadmium sulfide. The substrate can be glass. The compound semiconductor based photovoltaic device can further include a back contact such as a back metal contact over the semiconductor layer. The compound semiconductor based photovoltaic device can further include a transparent conductive layer over the substrate. The compound semiconductor based photovoltaic device can further include a second compound semiconductor layer over the first compound semiconductor layer.

Plasma treatments on compound semiconductor films can be performed in a vacuum or at atmospheric pressure. A plasma treatment can be used as part of an etching process. A plasma treatment can also be used as part of a surface, interface, or mid-gap state passivation process to improve electrical transport, adhesion and contact properties. A plasma treatment can be used for enhancing the long-term device performance under operating conditions.

A semiconductor layer can be exposed to a plasma treatment, before or after chemical processing, or prior to contact application.

In one example, 10×10 cm² samples of a thin film photovoltaic device including a CdTe layer were exposed to hydrogen plasma treatment after CdCl₂ treatment. Hydrogen plasma power settings were between 50W-200W with treatment times of 5-20 minutes. Chamber pressure was kept constant at 300 mTorr. Results included decreased Roc values, typically 0.2-8 Ohm lower for plasma treated devices than found for untreated devices, suggesting improved electrical contact properties. The devices were exposed to stress testing in light (1 AM) and heat (110 degrees Celsius-115 degrees Celsius). After 28 days of stress exposure, hydrogen plasma treated devices exhibited higher final conversion efficiencies (up 1.5) and lower Roc values (typically 0.2-8 Ohm lower) than standard devices.

A common photovoltaic cell can have multiple layers. The multiple layers can include a bottom layer that is a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic cell.

The bottom layer can be a transparent conductive layer, and can be, for example, a transparent conductive oxide such as tin oxide or tin oxide doped with fluorine. Deposition of a semiconductor layer at high temperature directly on the transparent conductive oxide layer can result in reactions that negatively impact of the performance and stability of the photovoltaic device. Deposition of a capping layer of material with a high chemical stability (such as silicon dioxide, dialuminum trioxide, titanium dioxide, diboron trioxide and other similar entities) can significantly reduce the impact of these reactions on device performance and stability. The thickness of the capping layer should be minimized because of the high resistivity of the material used. Otherwise a resistive block counter to the desired current flow may occur. A capping layer can reduce the surface roughness of the transparent conductive oxide layer by filling in irregularities in the surface, which can aid in deposition of the window layer and can allow the window layer to have a thinner cross-section. The reduced surface roughness can help improve the uniformity of the window layer. Other advantages of including the capping layer in photovoltaic cells can include improving optical clarity, improving consistency in band gap, providing better field strength at the junction and providing better device efficiency as measured by open circuit voltage loss. Capping layers are described, for example, in U.S. Patent Publication 20050257824, which is incorporated by reference in its entirety.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, InS, TlN, TlP, TlAs, TlSb, or mixtures or alloys thereof. An example of a window layer and absorbing layer is a layer of CdS coated by a layer of CdTe. A top layer can cover the semiconductor layers. The top layer can include a metal such as, for example, aluminum, molybdenum, chromium, cobalt, nickel, titanium, tungsten, or alloys thereof. The top layer can also include metal oxides or metal nitrides or alloys thereof.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports substrate into a series of one or more deposition stations for depositing layers of material on the exposed surface of the substrate. Conveyors are described in provisional U.S. application Ser. No. 11/692,667, which is hereby incorporated by reference.

The deposition chamber can be heated to reach a processing temperature of not less than about 450° C. and not more than about 700° C., for example the temperature can range from 450-550° C., 550-650° C., 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations with its own vapor distributor and supply. The distributor can be in the form of a spray nozzle with varying nozzle geometries to facilitate uniform distribution of the vapor supply.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The transparent conductive layer can be a transparent conductive oxide, such as a metallic oxide like tin oxide, which can be doped with, for example, fluorine. This layer can be deposited between the front contact and the first semiconductor layer, and can have a resistivity sufficiently high to reduce the effects of pinholes in the first semiconductor layer. Pinholes in the first semiconductor layer can result in shunt formation between the second semiconductor layer and the first contact resulting in a drain on the local field surrounding the pinhole. A small increase in the resistance of this pathway can dramatically reduce the area affected by the shunt.

A capping layer can be provided to supply this increase in resistance. The capping layer can be a very thin layer of a material with high chemical stability. The capping layer can have higher transparency than a comparable thickness of semiconductor material having the same thickness. Examples of materials that are suitable for use as a capping layer include silicon dioxide, dialuminum trioxide, titanium dioxide, diboron trioxide and other similar entities. Capping layer can also serve to isolate the transparent conductive layer electrically and chemically from the first semiconductor layer preventing reactions that occur at high temperature that can negatively impact performance and stability. The capping layer can also provide a conductive surface that can be more suitable for accepting deposition of the first semiconductor layer. For example, the capping layer can provide a surface with decreased surface roughness.

The first semiconductor layer can serve as a window layer for the second semiconductor layer. The first semiconductor layer can be thinner than the second semiconductor layer. By being thinner, the first semiconductor layer can allow greater penetration of the shorter wavelengths of the incident light to the second semiconductor layer.

The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, InS, TlN, TlP, TlAs, TlSb, or mixtures or alloys thereof. It can be a binary semiconductor, for example it can be CdTe. The second semiconductor layer can be deposited onto the first semiconductor layer. The second semiconductor can serve as an absorber layer for the incident light when the first semiconductor layer is serving as a window layer. Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, InS, TlN, TlP, TlAs, TlSb, or mixtures or alloys thereof. The first or second semiconductor layer can also be a group I-III-VI semiconductor, such as, for example, copper indium sulfide, copper indium gallium diselenide, or copper indium gallium diselenide sulfide, or mixtures or alloys thereof.

The second semiconductor layer can be deposited onto a first semiconductor layer. A capping layer can serve to isolate a transparent conductive layer electrically and chemically from the first semiconductor layer preventing reactions that occur at high temperature that can negatively impact performance and stability. The transparent conductive layer can be deposited on a substrate.

A number of embodiments have been described. Nevertheless, it will be understood that various modifications may be made without departing from the spirit and scope of the invention. For example, the semiconductor layers can include a variety of other materials, as can the materials used for the buffer layer and the capping layer. Accordingly, other embodiments are within the scope of the following claims.

What is claimed is:

1. A method of manufacturing a thin film photovoltaic device comprising:
depositing a compound semiconductor layer on a substrate; and
exposing the device to plasma, the plasma treating the layer.

2. The method of claim. 1 further comprising applying a back contact to the compound semiconductor layer.

3. The method of claim 2 wherein plasma treatment is applied before applying the back contact.

4. The method of claim 2 wherein plasma treatment is applied after applying the back contact.

5. The method of claim 1 further comprising applying a transparent conductive layer over the substrate.

6. The method of claim 1 further comprising applying a transparent conductive layer over a compound semiconductor layer.

7. The method of claim 1 further comprising applying a second compound semiconductor layer over the compound semiconductor layer.

8. The method of claim 1 further comprising providing electrical connections connected to the photovoltaic device for collecting electrical energy produced by the photovoltaic device.

9. The method of claim 1 further comprising exposing the compound semiconductor layer to cadmium chloride processing before plasma treatment.

10. The method of claim 1 wherein the plasma treatment is applied for approximately 5 minutes.

11. The method of claim 1 wherein the plasma treatment is applied for approximately 10 minutes.

12. The method of claim 1 wherein the plasma treatment is applied for approximately 20 minutes.

13. The method of claim 1 wherein the plasma treatment is applied for approximately 30 minutes.

14. The method of claim 1 wherein the plasma processing includes reactive ion etching.

15. The method of claim 1 wherein the plasma treatment is applied in a vacuum.

16. The method of claim 1 wherein the plasma treatment is applied at atmospheric pressure.

17. A compound semiconductor based photovoltaic device comprising:
a substrate; and
a plasma-treated compound semiconductor layer on a substrate.

18. The device of claim 17 wherein the plasma includes hydrogen plasma.

19. The device of claim 17 wherein the plasma includes nitrogen plasma.

20. The device of claim 17 wherein the plasma includes argon plasma.

21. The device of claim 17 wherein the plasma includes helium plasma.

22. The device of claim 17 wherein the plasma includes oxygen plasma.

23. The device of claim 17 wherein the compound semiconductor is cadmium telluride.

24. The device of claim 17 wherein the compound semiconductor is copper indium sulfide, copper indium gallium diselenide, or copper indium gallium diselenide sulfide.

25. The device of claim 17 wherein the substrate is glass.

26. The device of claim 17 further comprising a back metal contact over the semiconductor layer.

27. The device of claim 17 further comprising a transparent conductive layer over the substrate.

28. The device of claim 17 further comprising a transparent conductive layer over the compound semiconductor layer.

29. The device of claim 17 further comprising a second compound semiconductor layer over the compound semiconductor layer.

30. A system for generating electrical energy comprising:
a multilayered photovoltaic device, the photovoltaic device including
a substrate,
a plasma-treated compound semiconductor layer on a substrate and
electrical connections connected to the photovoltaic device for collecting electrical energy produced by the photovoltaic device.

31. The system of claim 30 wherein the plasma includes hydrogen plasma.

32. The system of claim 30 wherein the plasma includes nitrogen plasma.

33. The system of claim 30 wherein the plasma includes argon plasma.

34. The system of claim 30 wherein the plasma includes helium plasma.

35. The system of claim 30 wherein the plasma includes oxygen plasma.

36. The system of claim 30 wherein the compound semiconductor is cadmium telluride.

37. The system of claim 30 wherein the compound semiconductor is copper indium sulfide, copper indium gallium diselenide, or copper indium gallium diselenide sulfide.

38. The system of claim 30 wherein the substrate is glass.

39. The system of claim 30 further comprising a back contact over the compound semiconductor layer.

40. The system of claim 30 further comprising a transparent conductive layer over the substrate.

41. The system of claim 30 further comprising a transparent conductive layer over the compound semiconductor layer.

42. The system of claim 30 further comprising a second compound semiconductor layer over the compound semiconductor layer.
